(19) United States
(12) Patent Application Publication
(10) Pub. No.: US 2012/0001322 A1
(43) Pub. Date: Jan. 5, 2012

(54) DOUBLE MOLDED CHIP SCALE PACKAGE

(76) Inventors: Yong Liu, Scarborough, ME (US); Luke England, Portland, ME (US)

(21) Appl. No.: 12/828,592

(22) Filed: Jul. 1, 2010

(51) Int. Cl. H01L 23/498

(52) U.S. Cl. 257/737; 257/E23.068

(57) ABSTRACT

Chip scale semiconductor packages and methods for making and using the same are described. The chip scale semiconductor packages (CSPs) contain a die with an integrated circuit device, a patterned plating layer, and a second interconnect structure formed from a Cu etched substrate that has a portion of an upper surface connected to the patterned plating layer, a side surface, and a bottom surface. The die can be attached to the patterned plating layer by a first interconnect structure that uses wirebonding or that uses a flip chip attachment process. The CSP contains a double molded structure where a first molding layer encapsulates the die, the patterned plating layer, the first interconnect structure, and the upper surface of the second interconnect structure. The second molding layer encapsulates the side surface of the second interconnect structure without encapsulating the bottom surface of the second interconnect structure. With such a configuration, the second molding layer helps control warpage during the manufacturing process and no printed circuit board (PCB) substrate is needed when the package is used in an electronic device since the signal routing is performed by the second interconnect structure. Other embodiments are described.

### FIELD

This application relates generally to semiconductor devices and methods for making such devices. More specifically, this application relates to chip scale semiconductor packages and methods for making and using the same.

### BACKGROUND

Semiconductor devices containing integrated circuits (ICs) are used in a wide variety of electronic apparatus. The IC devices (or chips) comprise a miniaturized electronic circuit that has been manufactured on the surface of a substrate (or die) of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices can be fabricated in a layer-by-layer process that uses a combination of many steps, including imaging, deposition, etching, doping and cleaning. One of the latter steps in the semiconductor fabrication process forms the packaging that is used to protect the IC device from environmental hazards.

After it has been formed, the semiconductor package is often used in an ever growing variety of electronic applications, such as disk drives, USB controllers, portable computer devices, cellular phones, and so forth. Depending on the size of the die and the electronic application, the semiconductor package may be highly miniaturized and may need to be as small as possible.

### SUMMARY

This application relates to chip scale semiconductor packages and methods for making and using the same. The chip scale semiconductor packages (CSPs) contain a die with an integrated circuit device, a patterned plating layer, and a second interconnect structure formed from a Cu etched substrate that has a portion of an upper surface connected to the patterned plating layer, a side surface, and a bottom surface. CSPs are semiconductor packages that contain a die that is substantially the same as the package size. The die can be attached to the patterned plating layer by a first interconnect structure that uses wirebonding or that uses a flip chip attachment process. The CSP contains a double molded structure where a first molding layer encapsulates the die, the patterned plating layer, the first interconnect structure, and the upper surface of the second interconnect structure. The second molding layer encapsulates the patterned plating layer and the side surface of the second interconnect structure without encapsulating the bottom surface of the second interconnect structure. With such a configuration, the second molding layer helps control warpage during the manufacturing process and no printed circuit board (PCB) substrate is needed when the package is used in an electronic device since the signal routing is performed by the second interconnect structure.

### BRIEF DESCRIPTION OF THE DRAWINGS

The following description can be better understood in light of the Figures, in which:

FIG. 1 shows some embodiments of a method for making semiconductor packages containing a substrate with a plating layer;

FIGS. 2 and 3 depict some embodiments of a method for making semiconductor packages where a die has been connected to the plating layer using a first interconnect structure;

FIG. 4 depicts some embodiments of a method for making semiconductor packages showing a first molding layer;

FIG. 5 shows some embodiments of a method for making semiconductor packages showing an etched substrate forming a second interconnect structure and a second molding layer;

FIG. 6 shows some embodiments of a method for making semiconductor packages where optional solder bumps have been attached to the etched substrate;

FIGS. 7a and 7b depicts some embodiments of a method for making semiconductor packages with a BGA/LGA packaging type;

FIGS. 8a and 8b depicts some embodiments of a method for making semiconductor packages with a QFN packaging type;

FIGS. 9a and 9b depicts some embodiments of a method for making semiconductor packages with a QFN packaging type with a heat sink; and

FIGS. 10-11 depicts embodiments of semiconductor packages containing multiple dies.

The Figures illustrate specific aspects of the semiconductor packages and methods for making such packages. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and associated methods of making and using the packages can be implemented and used without employing these specific details. Indeed, the semiconductor packages and associated methods can be placed into practice by modifying the illustrated devices and methods and can be used in conjunction with any other apparatus and techniques conventionally used in the industry. For example, while the description below focuses on methods for making for semiconductor devices in the IC industry, it could be modified for other devices where chip scale packaging is needed, i.e., discrete devices, MEMS devices, LCD displays, or optoelectronics.

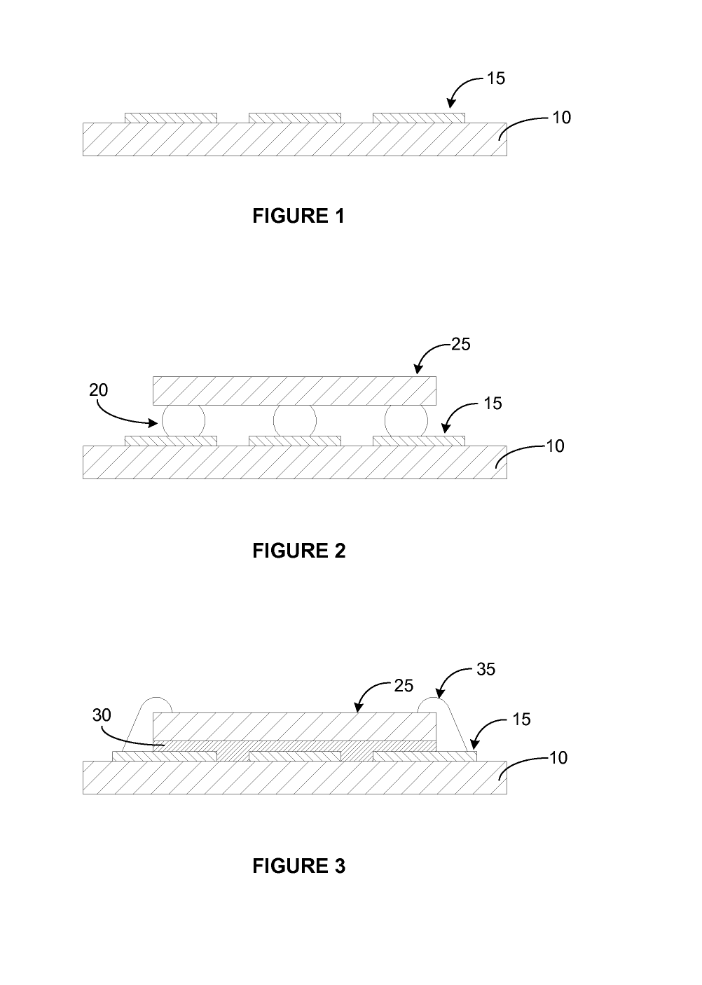

Some embodiments of the chip scale packages (CSP) and methods for making such packages are shown in the Figures. In these embodiments, the methods for making the semiconductor packages begin by providing a substrate 10, as shown in FIG. 1. The substrate 10 can comprise any conductive metal or metal alloy known in the art, including Cu, Ni—Pd, Ni—Pd—Au, Ni—Pd—Au/Ag, or combinations thereof. In some embodiments, the substrate 10 comprises Cu or a Cu alloy. The substrate 10 can be manufactured by any known process, such as a stamping, etching, or other metal forming process.

The substrate 10 can have any size and thickness that is needed to operate as a support substrate during the manufacturing process and yet can also be patterned to form interconnect structures as described below. Thus, the size and thickness of the substrate 10 will depend on the size and density of the semiconductor package, as well as the semiconductor die (or dies) that will be contained in semiconductor package. In some embodiments, the substrate 10 can be substantially rectangular with a size ranging from about 10,000 to about 20,000 mm² and a thickness ranging from about 0.10 to about 0.25 mm.

As shown in FIG. 1, a plating layer 15 can then be provided on the substrate 10. The plating layer (or plating) 15 will operate as landing pads and/or trace routings in the completed semiconductor packages. The plating 15 can therefore be formed of any conductive and plateable material known in the art, including Ni, Pd, or Au, or combinations thereof. In some embodiments, the plating 15 can be made of NiAu plated stack, where the Ni layer thickness ranges from about 1 to about 5 μm and the Au layer thickness ranges from about 0.1 to about 1.0 μm. The plating 15 can be formed using any process known in the art, including depositing the material of the layer (i.e., NiAu) by a plating process and then patterning that layer using any known masking and etching process.

Next, a semiconductor die 25 (or die) containing an IC device is attached to the plating 15 and the substrate 10. The die 25 may be made of any semiconductive material known in the art. Some non-limiting examples of such semiconductive materials include silicon, gallium arsenide, silicon carbide, gallium nitride, germanium, and combinations thereof.

The die 25 can contain any number of IC devices. The IC device may be any type of integrated circuit device known in the art. Some non-limiting examples of these IC devices may include logic or digital IC devices, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), insulated-gate field-effect transistors (“IGFET”), memory (RAM) or processors. In some embodiments, the IC device comprises an analog or power circuit(s).

The die 25 containing the IC device(s) can be attached to the plating 15 and the substrate 10 using any known processes. In the embodiments depicted in FIG. 2, the die 25 can be attached using any known flip chip process so that the active surface of the die 25 (or front surface) is electrically connected to the plating 15 using a first interconnect structure 20. Thus, in these embodiments, the plating 15 will not only serve as trace routes, but will also operate as landing pads in the completed semiconductor package.

In the flipchip process, the IC device(s) on the die 25 can be provided with bond pads (not shown) as known in the art. In some embodiments, the bond pads can be provided in those areas that overlay the IC device(s). In other embodiments the bond pads can be formed in the areas that do not overlay the IC device(s) but can be connected to the IC device(s) using a re-distribution layer. The bond pads can be formed using any process known in the art, including by electroplating. The bond pads can be made of any known solderable material, including Ni, Au, Cu, Ag, Pd, Sn, or combinations thereof.

As shown in FIG. 2, an interconnect structure 20 can be provided on the bond pads that are formed on the die 25. The interconnect structure 20 can comprise wire stud bumps, pillars, solder balls, or any other interconnect known in the art. The interconnect structure 20 can be made of any conductive material known in the art. In some embodiments, the interconnect structure can comprise any solderable material, such as Ag, Sn, Pb, Cu, Sb, Au, or combinations thereof. The interconnect structure 20 can be formed by any process that will provide the desired pattern on the die 25. In some embodiments, the interconnect structure 20 can be formed by using any known deposition, masking and etching process, as well as any dispensing, screen printing process, electro or electroless plating, ball drop, or wire stud bump process. Then, the die 25 is flipped and placed onto the plating 15 using a pick and place process so that the interconnect structures 20 are aligned with the pattern of the plating 15.

In other embodiments, the die 25 containing the IC device(s) can be attached to the plating 15 and substrate 10 using a wire bonding process, as shown in FIG. 3. In these embodiments, the active (or front) side of the die 25 can be made with contact pads (not shown) that are available for electrical connection to the wirebonds 35. Typically, these contact pads are located in the periphery of the die 25 and can be made by any process known in the art. The backside of the die 25 can then be provided with a die attach layer 30, such as any known non-conductive epoxy material. The backside of the die 25 is then connected to the plating 15 and the substrate 10, as shown in FIG. 3. The contact pads can then be electrically connected to the exposed parts of the plating in any known manner, including any known wire bonding process. The bonding wire 35 may be made of any wire bonding material, including Au, Cu, Pd, and combinations thereof and can be formed using any process known in the art.

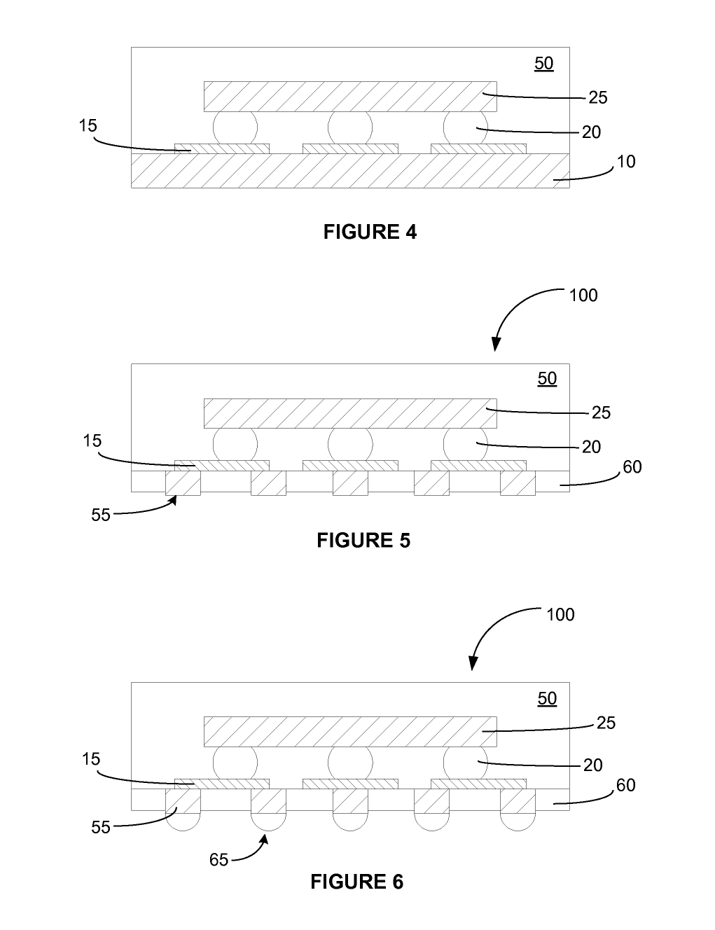

The resulting structure in both the wirebonding and flip chip embodiments can then be encapsulated in any first molding layer 50 known in the art, as shown in FIG. 4 (which shows the embodiments that use flip chip attachment method). The molding material of the first molding layer 50 is formed so that it surrounds the die, the interconnect structures 20 (or bond wires 35), the plating 15, and the upper surface of the substrate 10, but without encapsulating the sides or bottom of the substrate 10. The molding material of the first molding layer 50 can comprise an epoxy molding compound, a thermoset resin, a thermoplastic material, a potting material, or combinations thereof. In some embodiments, the molding material can comprise an epoxy molding compound. The first molding layer 50 may be formed using any encapsulation process known in the art, including a transfer molding process, a film assisted molding process, or a compression molding process.

The process for making the semiconductor package continues when the substrate 10 is patterned to form a second interconnect structure 55, as shown in FIG. 5. The second interconnect structure 55 can be formed using known masking and etching process known in the art which patterns the conductive material of the substrate 10. The second interconnect structure 55 can be provided with any pattern that can operate as an array of terminals for the completed semiconductor package. As illustrated in FIG. 5, the upper surface of the second interconnect structures 55 remain protected by the molding material 50 and or plating layer 15 during the process that is used to pattern the substrate 10. The plating layer 15 typically comprises a different metal than the substrate 10, which allows for selective metal etching when forming the interconnect structures 55.

Next, a second molding layer 60 can be formed around the sides of the second interconnect structure 55, leaving the bottoms of those structures exposed as illustrated in FIG. 5. With such a configuration, the plating 15 that operates as the routing traces can be encapsulated and protected by the combination of the first and second molding layers. The second molding layer 60 can comprise an epoxy molding compound, a thermoset resin, a thermoplastic material, potting material, or any combination thereof. In some embodiments, the molding material of the second molding layer 60 can comprise an epoxy molding compound. The second molding layer 60 may be formed using any encapsulation process known in the art, including a film assisted molding process, a film assisted molding process, or a compression molding process that leaves the bottom of the second interconnect structures 55 exposed. While the molding material 60 only encapsulates the sides of the second interconnect structures 55, it can cooperate with the first pre-molding layer 50 to completely encapsulate the rest of the components of the semiconductor package.

Optionally, a solder connector can be provided on the exposed bottom of the second interconnect structures 55. The solder connector can be used to connect the semiconductor package to an electronic device (i.e., a circuit board or printed circuit board) and, therefore, the specific type of solder connector can be selected with the specific electronic device in mind. In some embodiments, such as shown in FIG. 6, the solder connectors comprise solder bumps 65. The solder bumps 65 can comprise any known solder material, such as Sn, Pb, Ag, Cu, Sb, Au, or combinations thereof. The solder bumps and can be formed using any known bumping process, including a dispensing or screen printing process. In other embodiments, the solder connectors can comprise solder balls that can be formed using any known process, including a solder ball drop or printing process.

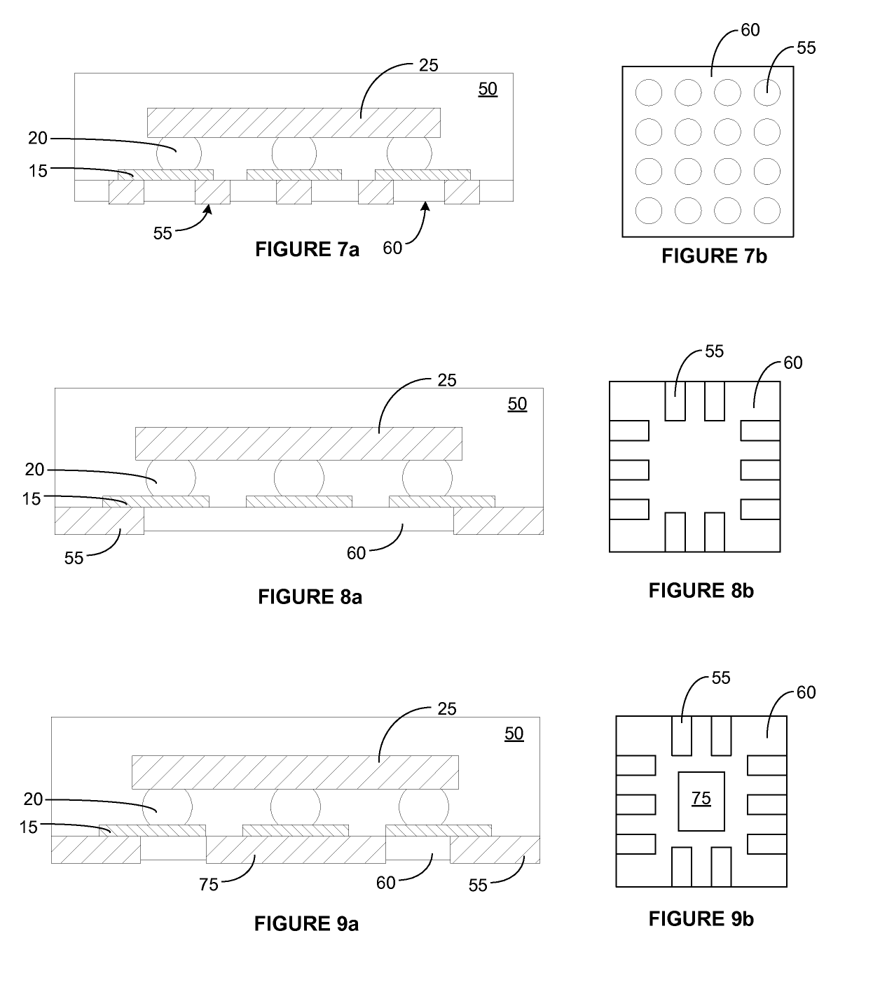

The exposed surfaces of the second interconnect structures 55 (with or without the solder connector) form an array of land pads or lands for the completed package. Thus, the second interconnect structures 55 can be configured with the desired type of semiconductor package in mind. For example, in addition to the ball grid array (BGA) package shown in FIG. 6, the second interconnect structures 55 can be configured to form a land grid array (LGA) type of package with no solder bumps, as shown in side view of FIG. 7a and the bottom view of FIG. 7b. In another example, the second interconnect structures 55 can be configured to form a quad flat no lead (QFN) type of package, as shown in the side view of FIG. 8a and the bottom view of FIG. 8b. In yet another example, the second interconnect structures 55 can be configured to form a QFN type of package containing a thermal pad (or heat sink) 75, as shown in the side view of FIG. 9a and the bottom view of FIG. 9b.

Since the semiconductor packages are manufactured in a double molded substrate format, only a singulation step is needed to obtain the final package. Following singulation of the double encapsulated substrate into individual packages, the completed semiconductor package may be electrically tested, taped, and reeled using any processes known in the art. These packages can then be used in any electronic device known in the art such as portable computers, disk drives, USB controllers, portable audio devices, or any other portable/ultraportable electronic devices.

One configuration of the completed semiconductor package 100 is shown in the side view of FIG. 5. The package 100 contains the semiconductor die 25 where the signal from IC device(s) can be routed through the bond pad, then through the first interconnect structure 20, through the plating layer 15, and then to the second interconnect structure 55. This pattern re-routes the electrical signals from the IC device(s) to the desired portion of the terminals (formed by the second interconnect structure 55). This pattern can therefore be routed and customized for a wide variety of packages configurations. This allows the semiconductor package 100 to be configured with many different sizes and shapes and used with different die sizes and shapes. The completed semiconductor package 100 also contains both the first molding layer 50 and the second molding material 60 that together encapsulate the package 100. The land pads/terminals formed by the second interconnect structure 55 remain exposed and are configured in a stand-off position so that they can be attached to the circuit board or other external device. In some configurations, the land pads/terminals formed by the second interconnect structure 55 may be substantially flush with the second molding layer 60.

The semiconductor packages formed by these methods have several features. First, the semiconductor packages contain an array of interconnect structures at the bottom of the package that can be configured for a wide variety of semiconductor package types. Second, the semiconductor packages contain a bottom molding layer that encapsulates the side surfaces of the interconnect structures that have been formed from an etched substrate. Since the signal routing is performed by the interconnect structure at the bottom of the package, such a configuration eliminates the need for a PCB substrate for re-routing the signal and, therefore, also reduces the manufacturing cost. The second molding layer can also act to control warpage during assembly processes, which becomes increasingly important as the device and package dimensions shrink. Finally, the semiconductor packages can use either flip chip or wire bond attach processes to attached the die 25 to the substrate 10.

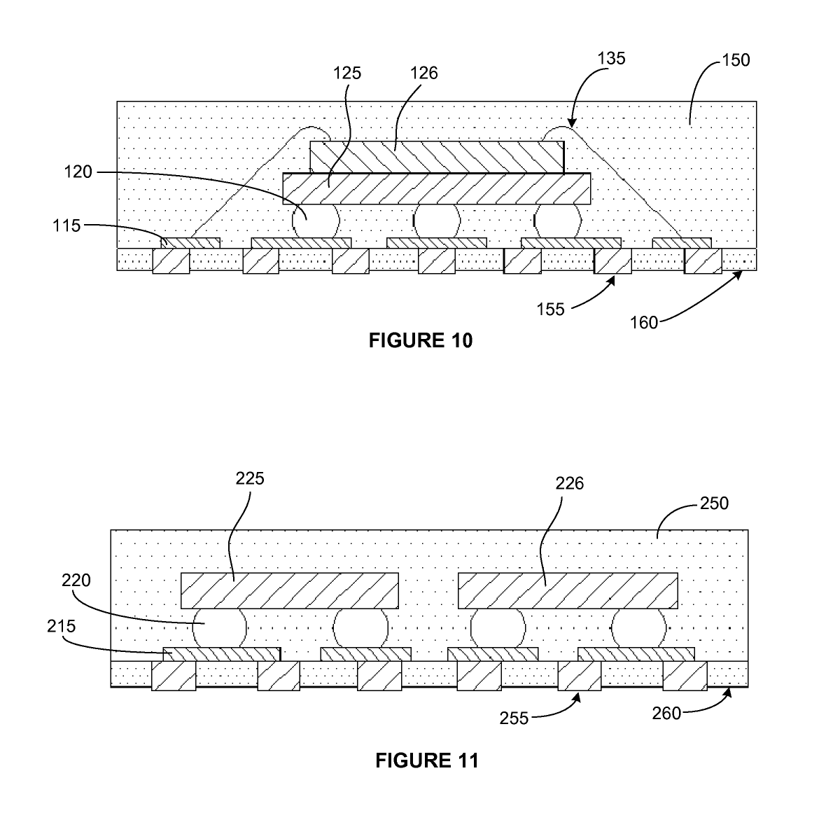

In some embodiments, the semiconductor packages can be configured to contain multiple dies. In the embodiments illustrated in FIG. 10, the semiconductor package contains a second die 126 has been stacked on first die 125 as known in the art. The first die 125 is connected to the patterned plating layer 115 using first interconnect structures 120. The second die has been connected to the patterned plating layer 115 using wirebonds 135. The package also contains first molding layer 150, second interconnect structures 155, and a second molding layer 160 similar to those described above.

In the embodiments shown in FIG. 11, the semiconductor package contains a second die 226 and a first die 225 as known in the art. The first die 225 and the second die 226 have been connected to the patterned plating layer 115 using first interconnect structures 220. The semiconductor package also contains first molding layer 250, second interconnect structures 255, and a second molding layer 260 similar to those described above.

In some embodiments, this application relates to a method for making a chip scale semiconductor package, comprising: providing a die containing an integrated circuit device; providing a patterned plating layer; providing a first interconnect structure that electronically connects the integrated circuit device and the patterned plating layer; providing a second interconnect structure formed from an etched substrate having a portion of an upper surface connected to the patterned plating layer, the second interconnect structure also having a side surface, and a bottom surface; providing a first molding layer encapsulating the die, the patterned plating layer, the first interconnect structure, and the upper surface of the second interconnect structure; and providing a second molding layer encapsulating the side surface of the second interconnect structure without encapsulating the bottom surface of the second interconnect structure.

In other embodiments, this application relates to a method for making a chip scale semiconductor package, comprising: providing a conductive substrate; forming a patterned plating layer on the conductive substrate; electrically connecting the integrated circuit device in a die to the patterned plating layer using a first interconnect structure; patterning the conductive substrate to form a second interconnect structure having a portion of an upper surface connected to the patterned plating layer, the second interconnect structure also having a side surface, and a bottom surface; encapsulating a first molding layer around the die, the patterned plating layer, the first interconnect structure, and the upper surface of the second interconnect structure; and encapsulating a second molding layer the side surface of the second interconnect structure without encapsulating the bottom surface of the second interconnect structure.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A chip scale semiconductor package, comprising:
a die containing an integrated circuit device connected to a patterned plating layer through a first interconnect structure;
a second interconnect structure formed from an etched substrate having a portion of an upper surface connected to the patterned plating layer, the second interconnect structure also having a side surface, and a bottom surface;
a first molding layer encapsulating the die, the patterned plating layer, the first interconnect structure, and the upper surface of the second interconnect structure; and
a second molding layer encapsulating the side surface of the second interconnect structure without encapsulating the bottom surface of the second interconnect structure.

2. The semiconductor package of claim 1, wherein the patterned plating layer comprises NiAu.

3. The semiconductor package of claim 1, wherein the integrated circuit device is connected to the patterned plating layer using wirebonding and the first interconnect structure comprises wirebonds.

4. The semiconductor package of claim 1, wherein the integrated circuit device is connected to the patterned plating layer using a flip chip attachment process and the first interconnect structure comprises wire studs.

5. The semiconductor package of claim 1, further comprising solder connectors on the exposed bottom surfaces of the second interconnect structure.

6. The semiconductor package of claim 1, wherein the second interconnect structure comprise Cu studs or pillars that are formed by patterning a Cu substrate.

7. The semiconductor package of claim 6, wherein the pattern of the Cu studs or pillars is configured for the type of semiconductor package.

8. The semiconductor package of claim 1, wherein the first molding layer and the second molding layer cooperatively encapsulate the package except for the bottom surface of the second interconnect structure.

9. A chip scale semiconductor package, comprising:
a die containing an integrated circuit device;
a patterned plating layer;
a first interconnect structure that electronically connects the integrated circuit device and the patterned plating layer;
a second interconnect structure formed from an etched substrate having a portion of an upper surface connected to the patterned plating layer, the second interconnect structure also having a side surface, and a bottom surface;
a first molding layer encapsulating the die, the patterned plating layer, the first interconnect structure, and the upper surface of the second interconnect structure; and
a second molding layer encapsulating the side surface of the second interconnect structure without encapsulating the bottom surface of the second interconnect structure.

10. The semiconductor package of claim 9, wherein the patterned plating layer comprises NiAu.

11. The semiconductor package of claim 9, wherein the integrated circuit device is connected to the patterned plating layer using wirebonding and the first interconnect structure comprises wirebonds.

12. The semiconductor package of claim 9, wherein the integrated circuit device is connected to the patterned plating layer using a flip chip attachment process and the first interconnect structure comprises wire studs.

13. The semiconductor package of claim 9, further comprising solder connectors on the exposed bottom surfaces of the second interconnect structure.

14. The semiconductor package of claim 9, wherein the second interconnect structures comprise Cu studs or pillars that are formed by patterning a Cu substrate.

15. (canceled)

16. The semiconductor package of claim 9, wherein the first molding layer and the second molding layer cooperatively encapsulate the package except for the bottom surface of the second interconnect structure.

17. An electronic device containing a chip scale semiconductor package without containing a PCB substrate, the package comprising:
a die containing an integrated circuit device;
a patterned plating layer;
a first interconnect structure that electronically connects the integrated circuit device and the patterned plating layer;
a second interconnect structure formed from an etched substrate having a portion of an upper surface connected to the patterned plating layer, the second interconnect structure also having a side surface, and a bottom surface;
a first molding layer encapsulating the die, the patterned plating layer, the first interconnect structure, and the upper surface of the second interconnect structure; and
a second molding layer encapsulating the side surface of the second interconnect structure without encapsulating the bottom surface of the second interconnect structure.

18. The electronic device of claim 17, wherein the patterned plating layer comprises NiAu.

19. The electronic device of claim 17, wherein the integrated circuit device is connected to the patterned plating layer using wirebonding and the first interconnect structure comprises wirebonds.

20. The electronic device of claim 17, wherein the integrated circuit device is connected to the patterned plating layer using a flip chip attachment process and the first interconnect structure comprises wire studs.

21. (canceled)

22. (canceled)

23. (canceled)

24. The electronic device of claim 17, wherein the first molding layer and the second molding layer cooperatively encapsulate the package except for a bottom surface of the second interconnect structure.
